(19) United States
(12) Patent Application Publication
(10) Pub. No.: US 2016/0240659 A1
(43) Pub. Date: Aug. 18, 2016

(54) LATERALLY DIFFUSED METAL OXIDE SEMICONDUCTOR DEVICE AND MANUFACTURING METHOD THEREFOR

(71) Applicant: CSMC TECHNOLOGIES FAB1 CO., LTD., Jiangsu (CN)

(72) Inventors: Guangsheng ZHANG, Wuxi New District (CN); Sen ZHANG, Wuxi New District (CN)

(21) Appl. No.: 15/026,193

(22) PCT Filed: Dec. 4, 2014
(86) PCT No.: PCT/CN2014/093057

§ 371 Date: Mar. 30, 2016

(30) Foreign Application Priority Data
Dec. 6, 2013 (CN) 201310661189.4

(51) Int. Cl. H01L 29/78; H01L 29/04; H01L 29/06; H01L 29/66

(52) U.S. Cl. CPC H01L 29/7816; H01L 29/66681; H01L 29/045; H01L 29/0684; H01L 29/0615; H01L 29/7838

(57) ABSTRACT

An LDMOS device, comprising a substrate (202), a gate electrode (211) on the substrate (202), a buried layer area in the substrate (202), and a diffusion layer on the buried layer area, wherein the buried layer area comprises a first buried layer (201) and a second buried layer (203), wherein the conduction types of impurities doped in the first buried layer (201) and the second buried layer (203) are opposite; the diffusion layer comprises a first diffusion area (205) and a second diffusion area (206), wherein the first diffusion area (205) is located on the first buried layer (201) and abuts against the first buried layer (201), and the second diffusion area (206) is located on the second buried layer (203) and abuts against the second buried layer (203); and the conduction types of impurities doped in the first buried layer (201) and the first diffusion area (205) are the same, and the conduction types of impurities doped in the second buried layer (203) and the second diffusion area (206) are the same. Additionally, also disclosed is a manufacturing method for the LDMOS device. A current path of the device in a conducting state is an area formed by the lower part of the second diffusion area (206) and the second buried layer (203) and is situated away from the surface of the device, so that the current capability of the device can be improved, the turn-on resistance can be reduced, and the reliability of the device can be improved.

### FIELD OF THE INVENTION

The present disclosure relates to semiconductor devices, and more particularly relates to an LDMOS device and a manufacturing method thereof.

### BACKGROUND OF THE INVENTION

During the manufacturing of the conventional high voltage devices, the voltage withstand layer is formed by either well with deeper junction depth or epitaxial layer with low concentration. The main disadvantages in these manners lie in that: 1, when using the well with deeper junction depth as voltage withstand region, the region with the highest impurity concentration is located on the surface of the device, when impurity with opposite conductivity type is implanted to the surface, the region with the highest impurity concentration will be neutralized, which results in an increasing Rdson; 2, when using the epitaxial layer as the voltage withstand region, the impurity concentration distribution thereof is uniform, such that it is difficult to decrease the Rdson of the device.

### SUMMARY OF THE INVENTION

Accordingly, it is necessary to provide a laterally diffused metal oxide semiconductor device with a low Rdson.

A laterally diffused metal oxide semiconductor device includes: a substrate; a gate located on the substrate; a buried layer region located in the substrate, the buried layer region comprising a first buried layer and a second buried layer, conductivity types of dopant impurities of the first buried layer and the second buried layer being opposite; and a diffusion layer located on the buried layer region, the diffusion layer comprising a first diffusion region and a second diffusion region, the first diffusion region being located on the first buried layer and being adjacent to the first buried layer; the second diffusion region being located on the second buried layer and being adjacent to the second buried layer; conductivity types of dopant impurities of the first buried layer and the first diffusion region being the same; conductivity types of dopant impurities of the second buried layer and the second diffusion region being the same; wherein the gate is located on the diffusion layer.

In one embodiment, the diffusion layer further includes a third diffusion region located in the second diffusion region; conductivity types of dopant impurities of the third diffusion region and the second diffusion region are opposite, an end of the gate is partially laminated on the third diffusion region.

In one embodiment, the laterally diffused metal oxide semiconductor device further includes a drain lead-out region, a source lead-out region, and a substrate lead-out region, which being located in the diffusion layer, wherein the other end of the gate is close to the source lead-out region.

In one embodiment, the source lead-out region and the substrate lead-out region are located in the first diffusion region, the drain lead-out region is located in the second diffusion region; the device is a normally-off type device.

In one embodiment, the substrate lead-out region is located in the first diffusion region; the drain lead-out region is located in the second diffusion region; at least partial source lead-out region is located in the second diffusion region; the device is a normally-on type device.

In one embodiment, the substrate is P-type substrate having a crystal orientation of (1 0 0).

A method of manufacturing a laterally diffused metal oxide semiconductor device is further provided.

A method of manufacturing a laterally diffused metal oxide semiconductor device includes the following steps: providing a substrate; forming a buried layer region in the substrate; wherein the buried layer region comprises a first buried layer and a second buried layer, conductivity types of dopant impurities of the first buried layer and the second buried layer are opposite; forming a silicon region on the buried layer region; implanting impurity ions to the silicon region and performing drive-in, thus forming a first diffusion region and a second diffusion region; wherein the first diffusion region is located on the first buried layer and is adjacent to the first buried layer; the second diffusion region is located on the second buried layer and is adjacent to the second buried layer; conductivity types of dopant impurities of the first buried layer and the first diffusion region are the same; conductivity types of dopant impurities of the second buried layer and the second diffusion region are the same; forming a gate oxide layer and a gate on the silicon region; and forming a source lead-out region, a drain lead-out region, and a substrate lead-out region; wherein the source lead-out region is located in the first diffusion region, the drain lead-out region is located in the second diffusion region, and the substrate lead-out region is located in the first diffusion region.

In one embodiment, after the implanting impurity ions to the silicon region and performing drive-in, forming the first diffusion region and the second diffusion region and prior to the forming the gate oxide layer and the gate on the silicon region, the method further comprises: forming a third diffusion region in the second diffusion region, wherein conductivity types of dopant impurities of the third diffusion region and the second diffusion region are opposite, an end of the gate is partially laminated on the third diffusion region, the other end of the gate is close to the source lead-out region.

In one embodiment, the source lead-out region and the substrate lead-out region are located in the first diffusion region, the drain lead-out region is located in the second diffusion region; the device is a normally-off type device.

In one embodiment, the substrate lead-out region is located in the first diffusion region; the drain lead-out region is located in the second diffusion region; at least partial source lead-out region is located in the second diffusion region; the device is a normally-on type device.

In the foregoing LDMOS device, the high voltage withstand region of the device is formed by the second buried layer and the second diffusion region, and it only takes a short time of high temperature drive-in, thus the production cost can be saved. After high temperature drive-in, the impurity concentration of the second buried layer is high, when the device is in a conducting state, the current path will be a region consisted of a lower portion of the second diffusion region and the second buried layer, which is away from the surface of the device, such that the current path can hardly be affected by the change of the impurity concentration of the surface of the device during the subsequent processes, thus increasing the current capability, reducing the Rdson, and increasing the reliability of the device.

### BRIEF DESCRIPTION OF THE DRAWINGS

FIG. 1 is a schematic view of a laterally diffused metal oxide semiconductor device (LDMOS);

FIG. 2 is a flow chart of a method of manufacturing a laterally diffused metal oxide semiconductor device in accordance with one embodiment;

FIGS. 3a to 3e are cross-sectional views of the laterally diffused metal oxide semiconductor device during manufacturing in accordance with one embodiment;

FIG. 4 is a cross-sectional view of a laterally diffused metal oxide semiconductor device in accordance with another embodiment.

### DETAILED DESCRIPTION OF THE EMBODIMENTS

The above objects, features and advantages of the present invention will become more apparent by describing in detail embodiments thereof with reference to the accompanying drawings.

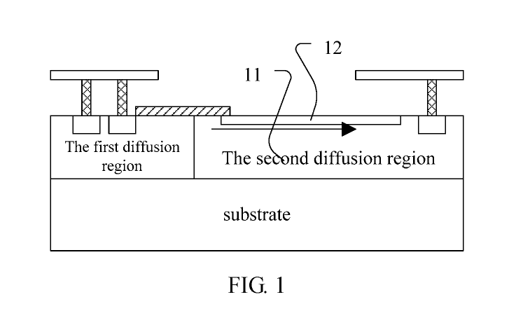

FIG. 1 is a schematic view of a conventional laterally diffused metal oxide semiconductor device (LDMOS). It can be seen that the junction depth of a first diffusion region 11 is deep, which needs a long time high temperature drive-in process to be formed, such that the production cost is increased. The arrow shown in the Fig represents the current path when the device is forwardly turned on. Since a portion of impurity concentration of the first diffusion region 11 in the current channel is neutralized by the region 12, the current capability becomes worse, and the conduction resistance is increased. In addition, the current flow area is close to the device surface, thus resulting in a poor reliability of the device.

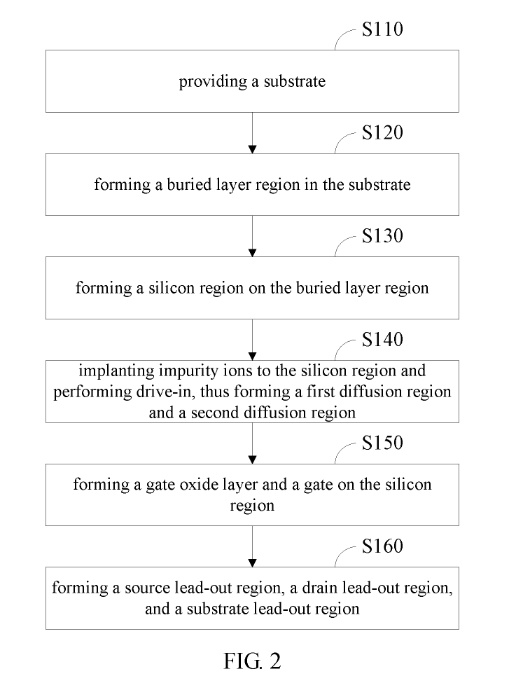

FIG. 2 is a flow chart of a method of manufacturing a laterally diffused metal oxide semiconductor device in accordance with one embodiment. The method includes the following steps:

In step S110, a substrate is provided.

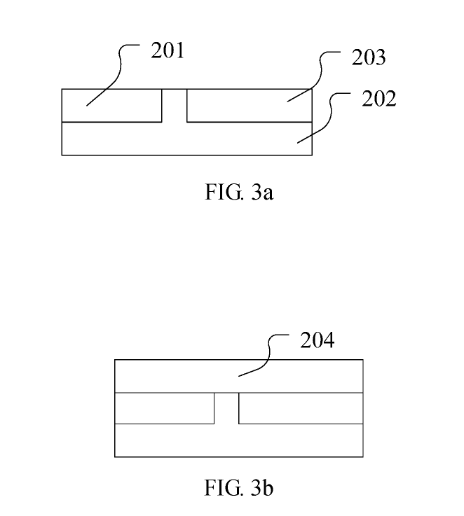

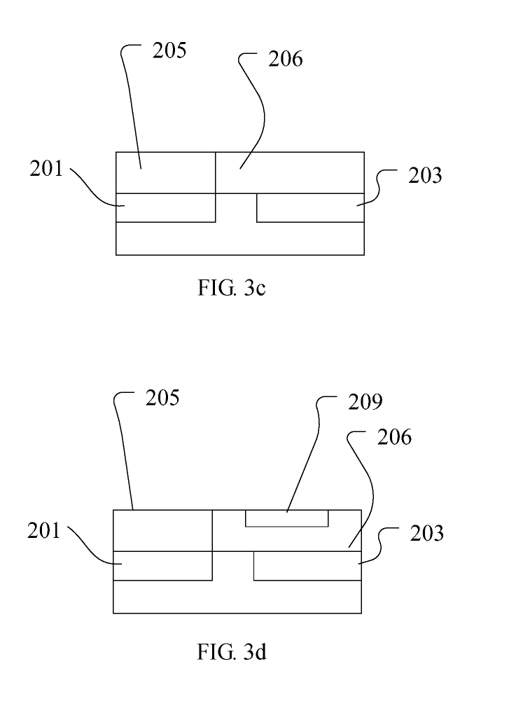

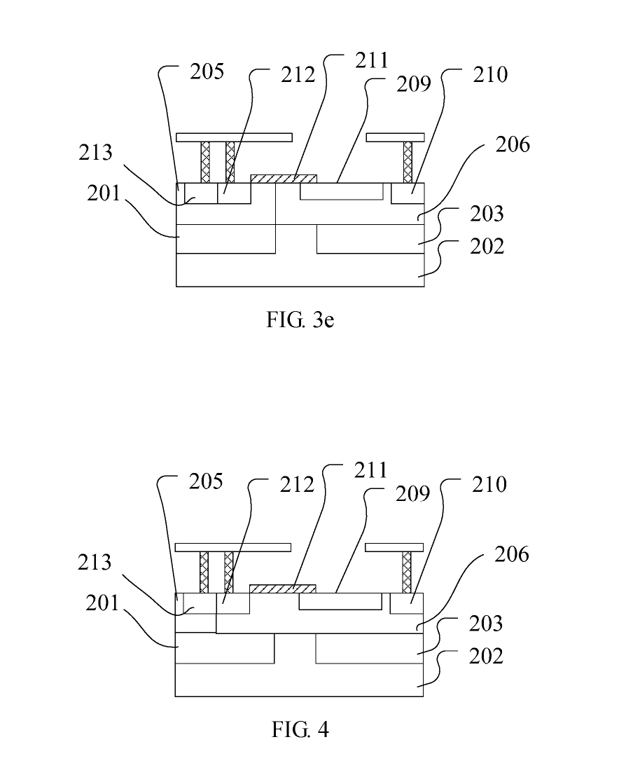

In the illustrated embodiment, to ensure a longitudinal withstand voltage of the device, referring to FIG. 3a, a P-type substrate 202 is employed, which has a low dopant concentration and a crystal orientation of (1 0 0).

In step S120, a buried layer region is formed in the substrate.

Referring to FIG. 3a, the buried layer region includes a first buried layer 201 and a second buried layer 203. Conductivity types of dopant impurities of the first buried layer 201 and the second buried layer 203 are opposite. The first buried layer 201 and the second buried layer 203 can be firmly attached together, or be spaced apart from each other. The first buried layer 201 and the second buried layer 203 can be formed by conventional implantation or other processes.

In step S130, a silicon region is formed on the buried layer region.

Referring to FIG. 3b, in the illustrated embodiment, conductivity types of dopant impurities of the silicon region 204 and the substrate 202 are the same. In alternative embodiment, the conductivity types of dopant impurities of the silicon region 204 and the substrate 202 can be opposite. The silicon region 204 can be formed by deposition and the like process.

In step S140, impurity ions are implanted to the silicon region and drive-in is performed, thus forming a first diffusion region and a second diffusion region.

Referring to FIG. 3c, after drive-in, the first diffusion region 205 and the second diffusion region 206 are connected to the first buried layer 201 and the second buried layer 203, respectively. The conductivity types of dopant impurities of the first diffusion region 205 and the second diffusion region 206 are opposite. The conductivity types of dopant impurities of the second diffusion region 206 and the second buried layer 203 are the same. The second buried layer 203 and the second diffusion region 206 cooperatively form a high voltage withstand region of the device.

In the illustrated embodiment, the first buried layer 201 and the second diffusion region 206 are connected at a corner. In alternative embodiments, the second diffusion region 206 can also partially cover the first buried layer 201. Referring to FIG. 3d, in the illustrated embodiment, after step S140, the method further includes: forming a third diffusion region 209 in the second diffusion region 206. Conductivity types of dopant impurities of the third diffusion region 209 and the second diffusion region 206 are opposite. The configuration of the third diffusion region 209 can enable the dopant concentration of the second diffusion region 206 to reach a highest level, thus decreasing the Rdson of the device.

In step S150, a gate oxide layer and a gate are formed on the silicon region.

In step S160, a source lead-out region, a drain lead-out region, and a substrate lead-out region are formed.

Referring to FIG. 3e, in the illustrated embodiment, the source lead-out region 212 is located in the first diffusion region 205, the drain lead-out region 210 is located in the second diffusion region 206, and the substrate lead-out region 213 is located in the first diffusion region 205. An end of the gate 211 is partially laminated on the third diffusion region 209, the other end of the gate 211 is close to the source lead-out region 212. The device of this structure is a normally-off type device.

Referring to FIG. 4, in the illustrated embodiment, the source lead-out region 212 is located in the second diffusion region 206, the drain lead-out region 210 is located in first diffusion region 205. The device of this structure is a normally-on type device.

In the foregoing LDMOS device, the high voltage withstand region of the device is formed by the second buried layer 203 and the second diffusion region 206, and it only takes a short time of high temperature drive-in, thus the production cost can be saved. After high temperature drive-in, the impurity concentration of the second buried layer 203 is high, when the device is in a conducting state, the current path will be a region consisted of a lower portion of the second diffusion region 206 and the second buried layer 203, which is away from the surface of the device, such that the current path can hardly be affected by the change of the impurity concentration of the surface of the device during the subsequent processes, thus increasing the current capability, reducing the Rdson, and increasing the reliability of the device.

FIG. 3e illustrates a laterally diffused metal oxide semiconductor device, which includes a substrate 202 and a gate 211 located on the substrate 202. The substrate 202 is provided with a buried layer region and a diffusion layer therein. The buried layer region includes a first buried layer 201 and a second buried layer 203, conductivity types of dopant impurities of the first buried layer 201 and the second buried layer 203 are opposite. The diffusion layer includes a first diffusion region 205 and a second diffusion region 206. The first diffusion region 205 is located on the first buried layer 201 and is adjacent to the first buried layer 201. The second diffusion region 206 is located on the second buried layer 203 and is adjacent to the second buried layer 203. Conductivity types of dopant impurities of the first buried layer 201 and the first diffusion region 205 are the same; conductivity types of dopant impurities of the second buried layer 203 and the second diffusion region 206 are the same. The source lead-out region 212 and the substrate lead-out region 213 are located in the first diffusion region 205, the drain lead-out region 210 is located in the second diffusion region 206. The gate 211 is located on the diffusion layer, one end of the gate 211 is partially laminated on the third diffusion region 209, the other end of the gate 211 is close to the source lead-out region 212.

In the illustrated embodiment, the substrate is P-type substrate having a crystal orientation of (1 0 0).

In the illustrated embodiment, the third diffusion region 209 is located in the second diffusion region 206; conductivity types of dopant impurities of the third diffusion region 209 and the second diffusion region 206 are opposite.

In the illustrated embodiment, the first buried layer 201 and the second diffusion region 206 are connected at a corner. The source lead-out region 212 is located in the first diffusion region 205, the device of this structure is a normally-off type device. In the embodiment illustrated in FIG. 4, the second diffusion region 206 partially covers the first buried layer 201, and the source lead-out region 212 is located in the second diffusion region 206, the device of this structure is a normally-on type device.

Although the description is illustrated and described herein with reference to certain embodiments, the description is not intended to be limited to the details shown. Modifications may be made in the details within the scope and range equivalents of the claims.

What is claimed is:

1. A laterally diffused metal oxide semiconductor device, comprising:
a substrate;
a gate located on the substrate;
a buried layer region located in the substrate, the buried layer region comprising a first buried layer and a second buried layer, conductivity types of dopant impurities of the first buried layer and the second buried layer being opposite; and
a diffusion layer located on the buried layer region, the diffusion layer comprising a first diffusion region and a second diffusion region, the first diffusion region being located on the first buried layer and being adjacent to the first buried layer; the second diffusion region being located on the second buried layer and being adjacent to the second buried layer; conductivity types of dopant impurities of the first buried layer and the first diffusion region being the same; conductivity types of dopant impurities of the second buried layer and the second diffusion region being the same;
wherein the gate is located on the diffusion layer.

2. The laterally diffused metal oxide semiconductor device according to claim 1, wherein the diffusion layer further comprises a third diffusion region located in the second diffusion region; conductivity types of dopant impurities of the third diffusion region and the second diffusion region are opposite, an end of the gate is partially laminated on the third diffusion region.

3. The laterally diffused metal oxide semiconductor device according to claim 2, further comprising a drain lead-out region, a source lead-out region, and a substrate lead-out region, which being located in the diffusion layer, wherein the other end of the gate is close to the source lead-out region.

4. The laterally diffused metal oxide semiconductor device according to claim 3, wherein the source lead-out region and the substrate lead-out region are located in the first diffusion region, the drain lead-out region is located in the second diffusion region; the device is a normally-off type device.

5. The laterally diffused metal oxide semiconductor device according to claim 3, wherein the substrate lead-out region is located in the first diffusion region; the drain lead-out region is located in the second diffusion region; at least partial source lead-out region is located in the second diffusion region; the device is a normally-on type device.

6. The laterally diffused metal oxide semiconductor device according to claim 1, wherein the substrate is P-type substrate having a crystal orientation of (1 0 0).

7. A method of manufacturing a laterally diffused metal oxide semiconductor device, comprising the following steps:
providing a substrate;
forming a buried layer region in the substrate; wherein the buried layer region comprises a first buried layer and a second buried layer, conductivity types of dopant impurities of the first buried layer and the second buried layer are opposite;
forming a silicon region on the buried layer region;
implanting impurity ions to the silicon region and performing drive-in, thus forming a first diffusion region and a second diffusion region; wherein the first diffusion region is located on the first buried layer and is adjacent to the first buried layer; the second diffusion region is located on the second buried layer and is adjacent to the second buried layer; conductivity types of dopant impurities of the first buried layer and the first diffusion region are the same; conductivity types of dopant impurities of the second buried layer and the second diffusion region are the same;
forming a gate oxide layer and a gate on the silicon region; and
forming a source lead-out region, a drain lead-out region, and a substrate lead-out region;
wherein the source lead-out region is located in the first diffusion region, the drain lead-out region is located in the second diffusion region, and the substrate lead-out region is located in the first diffusion region.

8. The method according to claim 7, wherein after the implanting impurity ions to the silicon region and performing drive-in, forming the first diffusion region and the second diffusion region and prior to the forming the gate oxide layer and the gate on the silicon region, the method further comprises: forming a third diffusion region in the second diffusion region, wherein conductivity types of dopant impurities of the third diffusion region and the second diffusion region are opposite, an end of the gate is partially laminated on the third diffusion region, the other end of the gate is close to the source lead-out region.

9. The method according to claim 7, wherein the source lead-out region and the substrate lead-out region are located in the first diffusion region, the drain lead-out region is located in the second diffusion region; the device is a normally-off type device.

10. The method according to claim 7, wherein the substrate lead-out region is located in the first diffusion region; the drain lead-out region is located in the second diffusion region; at least partial source lead-out region is located in the second diffusion region; the device is a normally-on type device.
